(19) United States
(12) Patent Application Publication
(10) Pub. No.: US 2024/0384410 A1
(43) Pub. Date: Nov. 21, 2024

(54) SYSTEM AND METHOD FOR PLASMA ENHANCED ATOMIC LAYER DEPOSITION WITH PROTECTIVE GRID

(71) Applicant: Taiwan Semiconductor Manufacturing Co., Ltd., Hsinchu (TW)

(72) Inventors: Wei-Hao LEE, Hsinchu (TW); Pei-Cheng HSU, Hsinchu (TW); Hsin-Chang LEE, Hsinchu (TW)

(21) Appl. No.: 18/787,915

(22) Filed: Jul. 29, 2024

Related U.S. Application Data
(62) Division of application No. 17/750,145, filed on May 20, 2022.
(60) Provisional application No. 63/271,542, filed on Oct. 25, 2021.

(51) Int. Cl. C23C 16/455; H01J 37/32

(52) U.S. Cl. CPC C23C 16/45544; C23C 16/45536; C23C 16/45553; H01J 37/32357; H01J 37/3244; H01J 2237/3321; H01J 2237/334

(57) ABSTRACT

A plasma enhanced atomic layer deposition (PEALD) system includes a process chamber. A target substrate is supported in the process chamber. A grid is positioned in the process chamber above the target substrate. The grid includes a plurality of apertures extending from a first side of the grid to a second side of the grid. During a PEALD process, a plasma generator generates a plasma. The energy of the plasma is reduced by passing the plasma through the apertures in the grid prior to reacting the plasma with the target substrate.

### BACKGROUND

There has been a continuous demand for increasing computing power in electronic devices including smart phones, tablets, desktop computers, laptop computers and many other kinds of electronic devices. One way to increase computing power in integrated circuits is to increase the number of transistors and other integrated circuit features that can be included for a given area of substrate.

To continue decreasing the size of features in integrated circuits, various thin-film deposition techniques, etching techniques, and other processing techniques are implemented. These techniques can form very small features. However, there are many difficulties involved in ensuring high performance of the devices and features.

Plasma assisted deposition and etching techniques can be useful in defining small features in integrated circuits. However, there are difficulties associated with ensuring that unintended damage does not occur to a target substrate when performing plasma assisted deposition or etching techniques. Some unconventional substrates, such as carbon nanotube substrates, may be particularly susceptible to damage when performing plasma based deposition processes. This can lead to poorly functioning integrated circuits or even scrapped targets.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a plasma enhanced processing system 100, in accordance with some embodiments.

FIGS. 2A and 2B are illustrations of a plasma enhanced thin-film deposition system, in accordance with some embodiments.

FIG. 3 is an illustration of a plasma enhanced thin-film deposition system, in accordance with some embodiments.

FIG. 4 is an illustration of a plasma enhanced thin-film deposition system, in accordance with some embodiments.

FIGS. 5A-5D are top view of grids for plasma enhanced thin-film deposition systems, in accordance with some embodiments.

FIGS. 6A and 6B are top views of a process chamber, in accordance with some embodiments.

FIGS. 7A-7D are enlarged cross-sectional views of grids for plasma enhanced thin-film deposition systems, in accordance with some embodiments.

FIGS. 8A-8D are side views of a target substrate during successive stages of a plasma enhanced thin-film deposition system, in accordance with some embodiments.

FIGS. 8E and 8F are top views of the target substrate of FIGS. 8A-8D, in accordance with some embodiments

FIG. 9 is a flow diagram of a method for performing a thin-film process on a target, in accordance with some embodiments.

FIG. 10 is a flow diagram of a method for performing a thin-film process on a target, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide a plasma enhanced atomic layer deposition (PEALD) process system that can safely perform PEALD processes on sensitive target substrates without damaging the target substrates. A target is supported in a process chamber. A grid is positioned above the target in the process chamber. The grid has a first side distal to the target, a second side proximal to the target, and a plurality of apertures extending between the first side and the second side. During a PEALD process, a plasma is reacted with the target. However, before the plasma is reacted with the target, the energy of the plasma is modified, e.g., reduced, by passing the plasma through the apertures of the grid.

Embodiments of the present disclosure provide several benefits. The reduction in plasma energy by the grid prevents the plasma from damaging the target substrate. As a result, fewer substrates or circuits need to be scrapped. Furthermore, circuits and devices have better performance and thin films have higher quality.

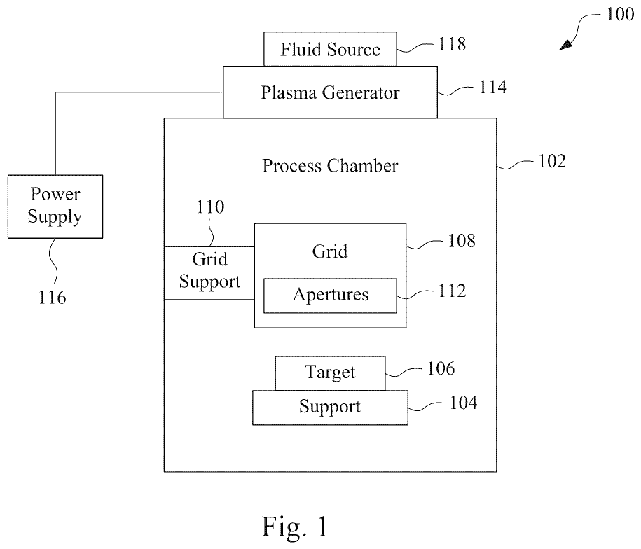

FIG. 1 is a block diagram of a plasma enhanced processing system 100, according to one embodiment. The plasma enhanced processing system 100 includes a process chamber 102, a target support 104 in the process chamber 102 of the plasma enhanced processing system 100, and a target 106 supported by the target support 104. The plasma enhanced processing system 100 includes a grid 108 supported in the process chamber 102 by a grid support 110. As will be set forth in more detail below, the components of the plasma enhanced processing system 100 cooperate to ensure that plasma enhanced processes can be performed on the target 106 without damaging the target 106.

In some embodiments, the plasma enhanced processing system 100 includes a plasma enhanced thin-film deposition system. A plasma enhanced thin-film deposition system utilizes plasmas to assist in depositing thin-films on the top surface of the target 106. One example of a plasma enhanced thin-film deposition system includes a plasma enhanced atomic layer deposition (PEALD) system. Other examples of plasma enhanced thin-film deposition systems can include plasma enhanced chemical vapor deposition (PECVD) systems, plasma enhanced physical vapor deposition (PEPVD) systems, or other types of plasma enhanced thin-film deposition systems.

In some embodiments, the plasma enhanced processing system 100 includes a plasma etching system. The plasma etching system utilizes plasma to assist in etching a thin-film on the surface of the target 106. Plasma etching systems can include dry etching systems or other types of etching systems. In one example, the plasma etching system includes a plasma enhanced atomic layer etching (PEALE) system.

The plasma enhanced processing system 100 includes a plasma generator 114, a power supply 116, and a fluid source 118. The power supply 116 is coupled to the plasma generator 114. The fluid source 118 is configured to provide a fluid into the process chamber 102.

During a plasma enhanced process, a fluid source 118 supplies a fluid into the plasma generator 114. The power supply 116 provides power to the plasma generator 114. The plasma generator 114 generates a plasma from the fluid provided by the fluid source 118. The plasma is output into the process chamber 102 from the plasma generator 114. The plasma includes particles that travel toward the target 106. The particles can include charged particles and radicals. As used herein, the term “charged particles” can include atoms that carry a net charge, molecules or compounds that carry a net charge, free electrons, and free protons (which may also be considered hydrogen ions). When the plasma encounters the target 106, the plasma interacts with the surface of the target 106 and performs an intended process on the target 106. For example, the plasma may contribute in depositing a thin-film or in etching a thin-film, as the case may be.

In some cases, the plasma generator 114 may generate plasma with very high energy. A high-energy plasma is one in which the charged particles and radicals have high kinetic energies. In some cases, it is possible that high-energy plasma particles may damage the target 106. Some types of targets may be particularly susceptible to damage from plasma particles. The target 106 may include a semiconductor wafer, a substrate within a thin layer of carbon nanotubes on the surface, or other types of substrates or surfaces on which a thin-film may be deposited.

In order to reduce the likelihood of damage to the target 106, the plasma enhanced processing system 100 includes the grid 108 positioned between the plasma generator 114 and the target 106. The grid 108 serves to reduce the energy of plasma particles that interact with the target 106. When plasma particles travel toward the target 106, the plasma particles will encounter the grid 108. The grid 108 reduces the energy of the plasma particles such that when the plasma particles encounter the target 106, the energy of the plasma particles is not sufficient to damage the target 106. The plasma particles are still able to perform the deposition or etching process, as the case may be.

In some embodiments, the grid 108 includes a plate or other solid structure that includes a plurality of apertures 112. The apertures 112 correspond to openings, holes, or passages through which plasma particles may travel in order to pass from one side of the grid 108 to the other side of the grid 108. For example, a first side of the grid 108 is distal from the target 106. A second side of the grid 108 is proximal to the target 106. Plasma particles travel from the distal side of the grid 108 to the proximal side of the grid 108 via the apertures 112.

The reduction in energy is achieved by some particles encountering the solid surface of the distal side of the grid 108 before eventually flowing through one of the apertures 112. A particle that flows directly through an aperture 112 without encountering the solid surface of the distal side of the grid 108 will not have a significant reduction in energy. A particle that impacts the solid surface of the distal side of the grid 108 will have a reduction in energy before eventually flowing into one of the apertures 112 toward the target 106. The result is that the average energy of the plasma particles is reduced by the grid 108 before reaching the target 106. In other words, in some embodiments, the energy of some particles of the plasma is reduced while the energy of other particles of the plasma is not reduced.

The size of the apertures and the spacing of the apertures can be selected to provide a desired reduction in the total or average energy of the plasma particles that reach the target 106. The larger the apertures 112, or the greater the number of the apertures 112, the smaller the reduction in energy of the plasma particles. In other words, the higher the ratio of solid surface to aperture at the distal side of the grid 108, the greater the reduction in energy of the plasma particles. In one embodiment, the ratio of aperture surface area to solid surface area is between 0.1 and 0.2.

In one example, the power supply 116 is a radiofrequency power supply. The power supply 116 supplies a radiofrequency voltage between electrodes or coils of the plasma generator 114. In some cases, a first electrode is grounded while a second electrode receives the radiofrequency voltage. The radiofrequency voltage may have a frequency between 500 kHz and 20 MHz, though other frequencies can be utilized without departing from the scope of the present disclosure.

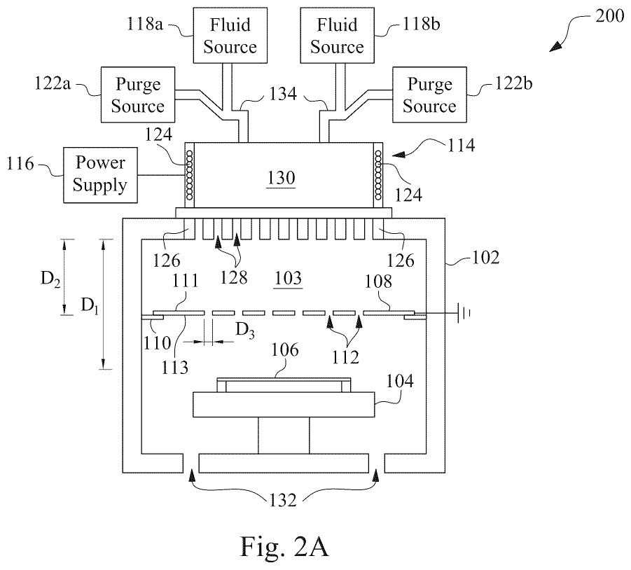

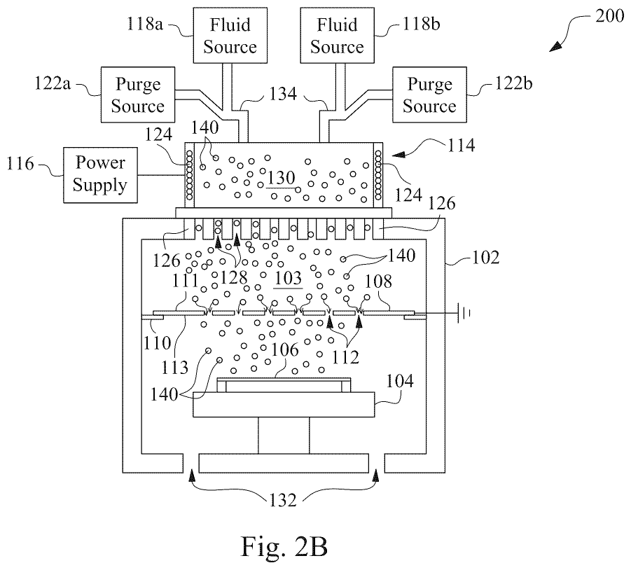

FIGS. 2A and 2B are illustrations of a PEALD system 200, in accordance with some embodiments. With reference to FIG. 2A, the PEALD system 200 includes a process chamber 102 including an interior volume 103. A target support 104 is positioned within the interior volume 103 and is configured to support a target 106 during a thin-film deposition process. The PEALD system 200 is configured to deposit a thin-film on the target 106. The PEALD system 200 includes a grid support 110 positioned within the interior volume 103. A grid 108 is supported on the grid support 110 above the target 106. As will be set forth in more detail below, the grid 108 helps to ensure that the target 106 is not damaged during thin-film deposition processes.

While the description of FIG. 2A primarily describes a PEALD system, principles of the present disclosure can be extended to PEALE systems and other types of deposition, etching, or semiconductor processing systems.

The PEALD system includes a plasma generator 114. The plasma generator 114 is positioned above the process chamber 102. The plasma generator 114 includes a plasma generation chamber 130. The plasma generator 114 generates a plasma within the plasma generation chamber 130. Further details regarding the plasma generator 114 will be provided below.

The PEALD system 200 includes a fluid inlet at the top of the process chamber 102. The fluid inlet may include a showerhead structure 126. The showerhead structure 126 includes a plurality of apertures 128. The plasma and other process fluids can be passed from the plasma generation chamber 130 into the interior volume 103 of the process chamber 102. The showerhead structure 126 may be utilized as an electrode as part of the plasma generation process. The showerhead structure 126 can have other configurations without departing from the scope of the present disclosure. Furthermore, plasma process fluids may be passed into the interior volume 103 via structures other than a showerhead structure 126.

In one embodiment, the PEALD system 200 includes a first fluid source 118a and a second fluid source 118b. The first fluid source 118a supplies a first fluid into the interior volume 103. The second fluid source 118b supplies a second fluid into the interior volume 103. The first and second fluids both contribute in depositing a thin-film on the target 106. While FIG. 2A illustrates fluid sources 118a and 118b, in practice, the fluid sources 118a and 118b may include or supply materials other than fluids. For example, the fluid sources 118a and 118b may include material sources that provide all materials for the depositing process.

The PEALD system performs depositing processes in cycles. Each cycle includes flowing a first process fluid from the first fluid source 118a, followed by purging the first process fluid from the process chamber by flowing the purge gas from one or both of the purge sources 122a and 122b. The purge fluid flows through the interior volume 103 and exits the interior volume 103 via one or more exhaust outlets 132, thereby carrying any remaining process fluids out of the interior volume 103 via the exhaust outlets 132. After the first purging process, a second process fluid is flowed from the second fluid source 118b into the interior volume 103, followed by purging the second process fluid from the process chamber by flowing the purge gas from one or both of the purge sources 122a and 122b. This corresponds to a single ALD cycle. Each cycle deposits an atomic or molecular layer of a thin-film on the target 106. In some embodiments, there may be more or fewer fluid sources and more or fewer stages in depositing a single atomic or molecular layer of a thin-film on the target 106.

In some embodiments, during the first stage of an ALD process, a precursor is flowed into the interior volume 103 via the showerhead structure 126. The precursor may be flowed from the first fluid source 118a. The precursor is adsorbed onto the exposed surface of the target 106. The precursor forms a layer that is one atom or molecule thick. The precursor may be flowed through the plasma generator 114 without operating the plasma generator 114 such that the plasma is not generated while flowing the precursor from the first fluid source 118a. A purge gas is then flowed from either or both of the purge sources 122a and 122b into the interior volume 103 in order to clear out any remaining precursors or byproducts of the precursor from the process chamber 102 via the exhaust outlets 132.

A second process fluid is then flowed from the second fluid source 118b into the plasma generation chamber 130. In this case, the power supply 116 supplies power to the plasma generator 114 in order to generate a plasma from the second process fluid within the plasma generation chamber 130. The plasma then flows from the plasma generation chamber 130 into the interior volume 103 of the process chamber 102 via the apertures 128 of the showerhead structure 126. The plasma includes high energy ions, radicals, and charged particles. The ions, radicals, and charged particles bombard the target 106, reacting with the atomic or molecular layer that was formed on the target 106 by the precursor. The reaction changes the atomic or molecular layer, thereby completing the first layer of the thin-film deposition. A second purging step can then be performed by flowing a purge fluid from either or both of the purge sources 122a and 122b into the interior volume 103 and out through the exhaust outlets 132.

In some cases, it can be possible that the target 106 can be damaged during bombardment by the plasma. In these cases, rather than merely completing the formation of an atomic or molecular layer of a desired composition, the plasma may break apart portions of the target 106 in an undesirable manner. This can occur with various types of targets 106. In one example, the target 106 includes a substrate of carbon nanotubes on which a thin-film is to be deposited by a PEALD process. However, the plasma stage of the PEALD process may cause substantial damage to the carbon nanotube substrate. Other types of substrates may also be damaged, such as semiconductor substrates, dielectric substrates, conductive substrates, or other types of substrates. Accordingly, while some particular examples are provided in which the target 106 includes the carbon nanotubes substrate, other types of targets can be utilized without departing from the scope of the present disclosure.

The PEALD system 200 advantageously reduces or prevents damage to the target 106 during the plasma stage of the PEALD process by utilizing the grid 108. The grid 108 is supported above the target 106 by grid supports 110 coupled to the interior walls of the process chamber 102. The grid 108 serves to reduce the energy of plasma particles that interact with the target 106. When plasma particles travel toward the target 106, the plasma particles will encounter the grid 108. The grid 108 reduces the energy of the plasma particles such that when the plasma particles encounter the target 106, the energy of the plasma particles is not sufficient to damage the target 106. The plasma particles are still able to perform the deposition or etching process, as the case may be.

In some embodiments, the grid 108 includes a plate or other solid structure that includes a distal side 111 and the proximal side 113. The proximal side 113 is proximal to the target 106. The distal side 111 is distal from the target 106. The grid 108 also includes a plurality of apertures 112 extending from the distal side 111 to the proximal side 113. The apertures 112 correspond to openings, holes, or passages through which plasma particles may travel in order to pass from one side of the grid 108 to the other side of the grid 108. For example, plasma particles travel from the distal side of the grid 108 to the proximal side of the grid 108 via the apertures 112.

The reduction in energy is achieved due to the fact that many or most of the plasma particles will encounter the solid surface of the distal side 111 rather than flowing directly into one of the apertures 112. When a plasma particle impacts the solid surface of the distal side 111, the plasma particle will lose some of its kinetic energy. Pressure differentials of and general fluid flow will eventually carry the plasma particles of reduced energy through the apertures 112. Many of the plasma particles 140 will encounter the target 106 and will perform the desired function of reacting with the precursor layer in order to complete an atomic or molecular layer of the thin-film on the target 106. Enough energy will be lost in the aggregate by the plasma particles 140 via the grid 108, that the target 106 will not be damaged by the plasma particles. The grid 108 reduces the impact and the mean free path of plasma particles. The plasma particles will still accomplish their role in the ALD process without causing substantial damage to the target 106.

While FIG. 2A illustrates a grid 108 having apertures 112 having substantially vertical cross-sections between the distal side 111 and the proximal side 113, the apertures 112 may have other cross-sectional shapes. For example, the apertures 112 may be tapered such that the apertures are larger in surface area at the distal side 111 than at the proximal side 113, or such that the apertures are smaller in surface area at the distal side 111 than at the proximal side 113. The apertures 112 may have non-linear, e.g., curved cross-sections, stepped cross-sections, or other shapes. When viewed from the top or bottom, the apertures 112 may have a circular, rectangular, square, ovular, elliptical, or with other shapes.

A particle that flows directly through an aperture 112 without encountering the solid surface of the distal side of the grid 108 may not have a significant reduction in energy. A particle that impacts the solid surface of the distal side 111 of the grid 108 will have a reduction in energy before eventually flowing into one of the apertures 112 toward the target 106. The result is that the average energy of the plasma particles is reduced by the grid 108 before reaching the target 106.

The size of the apertures 112 and the spacing of the apertures 112 can be selected to provide a desired reduction in the total or average energy of the plasma particles that reach the target 106. The larger the apertures 112, or the greater the number of the apertures 112, the smaller the reduction in energy of the plasma particles. In other words, the higher the ratio of solid surface to aperture at the distal side of the grid 108, the greater the reduction in energy of the plasma particles.

The distance D1 between the target support 104 and the bottom of the showerhead structure 126 may be between 20 mm and 300 mm. When D1 is less than 20 mm, there may not be sufficient height for the thickness of the samples and the grid. In one embodiment, when D1 is greater than 20 mm, sufficient height is reserved for the thickness of the samples and the grid. In one embodiment, if D1 is greater than 300 mm, the flow field in the chamber could be difficult to control and the energy of plasma particles could decrease dramatically.

FIG. 2A illustrates a system in which the plasma generator 114 is above the process chamber 102. In such a system, the distance D1 may be relatively large. However, in other systems, such as capacitively coupled plasma generators, the plasma generator 114 may include electrodes positioned within the process chamber 102 relatively close to the target 106. In these cases, the distance D1 may be relatively small. In each case, the grid 108 is positioned in the travel path of plasma particles prior to encountering the target 106. Other distances than those described above may be utilized without departing from the scope of the present disclosure.

The grid 108 may be separated from the showerhead structure 126 by a dimension D2. The dimension D2 may correspond to the distance between the distal side 111 and the bottom of the showerhead structure 126. The dimension D2 may be greater than 1 mm. This distance may be sufficient to ensure that no arcing occurs between the grid 108 and the showerhead structure 126 in embodiments in which the shower head structure 126 is utilized as an electrode for plasma generation. In some embodiments, D2 may be less than 1 mm provided arcing between grid 108 and the showerhead structure 126 is avoided. The distance between proximal side 113 and target 106 will be a function of D1 and D2. In some embodiments, the distance between proximal side 113 and target 106 is approximately equal to the difference between D1 and D2. The distance between proximal side 113 and target 106 should not be so small that the efficacy of the reduced energy of the plasma is decreased.

The apertures 112 may have a lateral dimension D3 between 1 mm and 30 mm. Embodiments in accordance with the present disclosure are not limited to D3 within this range. For example, D3 can be less than 1 mm, provided manufacturing a grid with apertures 112 having a lateral dimension D3 is not unreasonably challenging. In other embodiments, D3 can be greater than 30 mm, provided sufficient reduction in plasma energy is achieved. As described above, the lateral dimension may be constant from distal side 111 to proximal side 113 as shown in FIG. 2A or may be variable, such as in the case of curved, tapered, stepped, or other shapes of apertures 112. Accordingly, the apertures 112 may have a first dimension at the distal side 111 and a second dimension at the proximal side 113 larger than or smaller than the first dimension.

In some embodiments, the grid 108 may include metal. The metal can include stainless steel, tungsten, or an aluminum alloy. Stainless steel may have a benefit of being sufficiently hard and strong and resistant to heat damage. Stainless steel can be welded and when its surface has been fully passivated, chemical reactions with such surface do not occur. Tungsten may be beneficial because it has a high melting point and can withstand high temperature processes. An aluminum alloy may be beneficial because it is low cost, low weight, has high thermal conductivity and low magnetic permeability. Other metals and alloys can be utilized for the grid 108 without departing from the scope of the present disclosure.

In some embodiments, the grid 108 can include a ceramic material. The ceramic material can include quartz, Y₂O₃, ZrO₂, Al₂O₃, SiO₂, B₂O₃, Er₂O₃, Nd₂O₃, Nb₂O₅, CeO₂, Sm₂Os, Yb₂O₃, or Y₂O₃, Al₂O₃, ZrO₂ or coatings of these materials on the metal grids described above. Other ceramic materials can be utilized without departing from the scope of the present disclosure. Ceramic material may be beneficial because it is resistant to corrosion, high temperatures and abrasion.

In some embodiments, the grid 108 can include a rare earth fluoride. The rare earth fluoride can include fluorides of scandium (Sc), yttrium (Y), iridium (Ir), rhodium (Rh), lanthanum (La), cerium (Ce), europium (Eu), dysprosium (Dy), or erbium (Er)), or hafnium (Hf) or coatings of these materials on the metal grids described above. A rare earth fluoride can increase the strength and thermal conductivity of the grid 108.

In some embodiments, the grid 108 includes a low thermal expansion material such as oxide, nitride, boride, carbide, or coatings of these materials. Other low thermal expansion materials can be utilized without departing from the scope of the present disclosure.

The grid 108 may include a foil, a rigid structure plate, or other materials, shapes, or consistencies. The grid may be electrically grounded. Alternatively, the grid may be biased with a voltage other than ground.

The plasma enhanced processing system 100 may include a motor coupled to the grid 108. The motor may move the grid into position for a plasma assisted process. After the plasma assisted process, the motor may move the grid 108 out of position for non-plasma processes so that the grid does not influence the non-plasma processes.

The plasma generator 114 may include conductive coils 124. Voltages may be applied to the conductive coils 124 in order to generate a plasma within the plasma generation chamber 130. In one example, the power supply 116 is a radiofrequency power supply to the conductive coils 124. The radiofrequency voltage may have a frequency between 500 kHz and 20 MHz, though other frequencies can be utilized without departing from the scope of the present disclosure.

FIG. 2B illustrates the PEALD system 200 of FIG. 2A during the second stage of depositing a layer of a thin-film in which a plasma is generated from the process fluid. A process fluid flows from the second fluid source 118b through a fluid pipe 134 into the plasma generation chamber 130. The power supply 116 provides power to the conductive coils 124, thereby generating a plasma from the second process fluid. The plasma includes plasma particles 140. As used herein, the term “plasma particles” includes but is not limited to ions, electrons, protons, and radicals. The plasma particles 140 flow from the plasma generation chamber 130 through the apertures 128 of the showerhead structure 126 into the interior volume 103 of the process chamber 102. The plasma particles 140 may initially have a very high energy. However, at least a portion of the plasma particles encounter the surface of the distal side 111 of the grid 108 and lose some of their energy. These plasma particles flow along the surface of the distal side 111 until they encounter an aperture 112 and flow through the apertures 112 to the proximal side 113 of the grid 108. Other plasma particles may not contact the distal side of the grid 108 and may pass directly through the grid 108 via apertures 112. These plasma particles 140 may then proceed to encounter the target 106. Though not shown in FIG. 2B, plasma particles 140 may also flow around the edges of the grid 108 and pass through gaps in the grid support 110. During a subsequent purging cycle, the plasma particles 140 will flow out of the process chamber 102 through the exhaust outlets 132

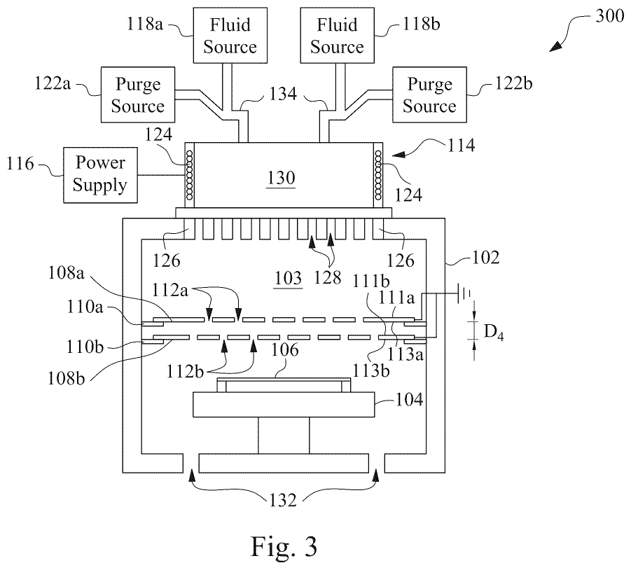

FIG. 3 is an illustration of a PEALD system 300, in accordance with some embodiments. The PEALD system 300 is substantially similar to the PEALD system 200 in most respects. The PEALD system 300 differs from the PEALD system 200 in that the PEALD system 300 includes a first grid 108a supported by a first grid support 110a and a second grid 108b supported by a second grid support 110b. The first grid 108a includes a distal side 111a, a proximal side 113a, and apertures 112a. The second grid 108b includes a distal side 111b, a proximal side 113b, and apertures 112b. The first grid 108a and the second grid 108b may be substantially similar to each other except that the apertures 112a and 112b are laterally offset from each other such that a plasma particles 140 that travels vertically downward through an aperture 112a will encounter the solid surface of the distal side 111b of the second grid 108b before flowing through an aperture 112b of the second grid 108b.

Accordingly, the first and second grids 108a and 108b together may reduce the energy of the plasma particles 140 more than either grid would alone. Accordingly, plasma particles 140 will encounter the solid surface of the distal side 111a, then flow through an aperture 112a, then encounter the distal side 111b, before flowing through an aperture 112b. This results in a larger decrease in energy of the plasma particles 140 before the plasma particles encounter the target 106 compared to if only one of grids 108a or 108b were present.

In some embodiments, the first grid 108a is separated from the second grid 108b by a vertical dimension D4. The vertical dimension D4 may be between 1 mm and 10 mm. When the vertical dimension D4 is outside this range, the ions may not hit the grid in a short time, so as to achieve the purpose of reducing ion energy. Moreover, if the D4<1 mm, precursors or particles may block the pipeline or apertures and hinder the operation of the grid.

In other embodiments, D4 is less than 1 mm or greater than 10 mm. D4 should be sufficient to ensure that plasma particles will have a reduction in energy while still being able to flow through both grids toward the target 106. However, other values of the vertical dimension D4 can be utilized without departing from the scope of the present disclosure.

While FIG. 3 illustrates two grids 108a and 108b, in practice a system 300 may include three or more grids positioned with offset apertures. Furthermore, the grids may have differing numbers of apertures, differing sizes of apertures, differing shapes of apertures, and different materials. In one embodiment, the apertures gradually decrease in size from the upper grids to the lower grids. In other embodiments, the apertures increase in size from the upper grids to the lower grids. Furthermore, the grids themselves may have different sizes. For example, higher grids may be smaller than lower grids in accordance with the chamber shape. Accordingly, differing numbers of grids can be utilized without departing from the scope of the present disclosure. In some embodiments, individual grids may include apertures of different sizes, e.g., different surface areas at the distal or at the proximal surfaces, or apertures of different shapes.

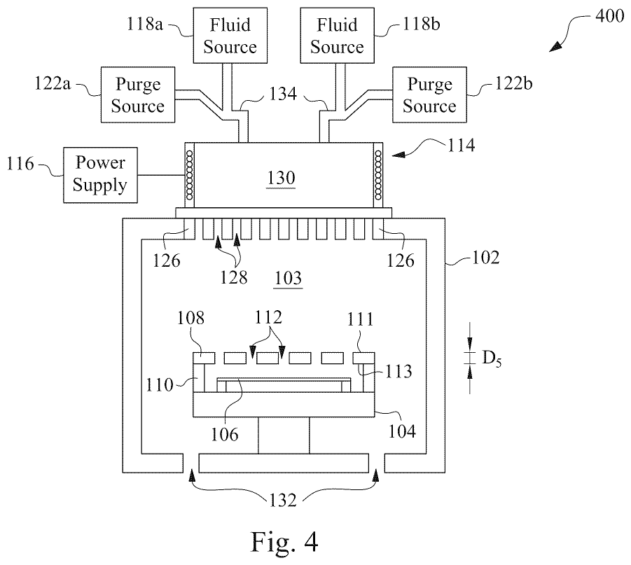

FIG. 4 is an illustration of a PEALD system 400, in accordance with some embodiments. The PEALD system 400 is substantially similar to the PEALD system 200 of FIG. 2A, except that the grid 108 is positioned differently in the PEALD system 400. In particular, the PEALD system 400 includes a grid support 110 positioned on the target support 104. In particular, the grid support 110 is positioned laterally around the target 106. The grid 108 rests on the grid support 110 above the target 106. The grid 108 is positioned a dimension D5 above the target 106. The dimension D5 may be between 5 mm and 100 mm, though other distances can be utilized without departing from the scope of the present disclosure. The grid 108 can be easily removed and replaced again in the interior volume 103 of the process chamber 102. In some embodiments, the grid support 110 may also be easily removed and replaced. In some embodiments, the grid support 110 and the grid 108 are fixed together. In some embodiments, the grid support 110 and the grid 108 may be integral with each other. In some embodiments, the grid 108 merely rests on the grid support 110. Though not shown in FIG. 4, multiple grids 108 can be utilized in the PEALD system 400 similar to the PEALD system 300, e.g., by stacking one or more grids on grid 108 using spacers to separate the grids.

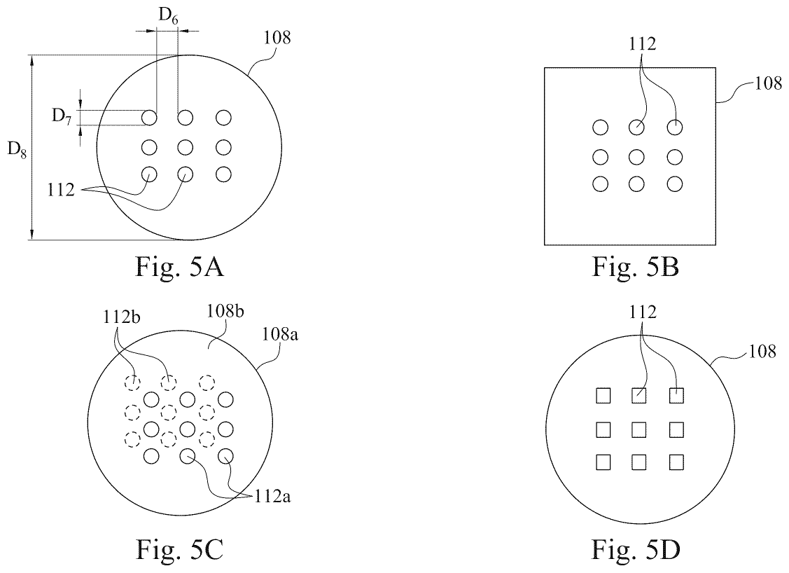

FIG. 5A is a top view of a grid 108, in accordance with some embodiments. The grid 108 of FIG. 5A is one example of a grid 108 that can be utilized in the systems of FIGS. 1-4. The grid 108 of FIG. 5A is circular. Each aperture 112 is separated from adjacent apertures 112 by a dimension D6. The dimension D6 may be between 5 mm and 50 mm, though other dimensions may be utilized without departing from the scope of the present disclosure. Each aperture 112 has a lateral dimension D7. The lateral dimension D7 may be between 1 mm and 30 mm. Apertures 112 smaller than 1 mm may be difficult to manufacture. Apertures 112 greater than 30 mm may result in reduced efficacy in preventing damage to a target 106 by failing to reduce energy of plasma particles a sufficient amount. Nevertheless, the apertures 112 can have other dimensions than these without departing from the scope of the present disclosure. For example, in some embodiments, D7 can be less than 1 mm or greater than 30 mm. The grid 108 is circular and has an overall dimension (or diameter) D8. The dimension D8 may be between 100 mm and 400 mm, though other dimensions may be utilized without departing from the scope of the present disclosure. In accordance with some embodiments, a ratio of D6 to D7 is between 50:1 and 1:6.

FIG. 5B is a top view of a grid 108, in accordance with some embodiments. The grid 108 of FIG. 5B is rectangular in shape with circular apertures 112. The grid of FIG. 5B is one example of a grid 108 that can be utilized in the systems of FIGS. 1-4. The dimensions associated with the grid 108 of FIG. 5B can be similar to those described in relation to FIG. 5A.

FIG. 5C is a top view of multiple grids 108a and 108b, in accordance with some embodiments. The second grid 108b is positioned below and is obscured by the first grid 108a. The apertures 112a of the first grid 108a are laterally offset from the apertures 112b of the second grid 108b. The grids 108a and 108b are one example of grids that can be utilized in the system of FIG. 3, though other types of grids can also be utilized without departing from the scope of the present disclosure. The grids 108a and 108b may be configured such that the apertures 112b are laterally positioned approximately halfway between the apertures 112a. The grids 108a and 108b can have substantially similar dimensions as described in relation to FIG. 5A.

FIG. 5D is a top view of a grid 108, in accordance with some embodiments. The grid 108 of FIG. 5B is circular in shape with square apertures 112. The grid of FIG. 5B is one example of a grid 108 that can be utilized in the systems of FIGS. 1-4. The dimensions associated with the grid 108 of FIG. 5D can be similar to those described in relation to FIG. 5A.

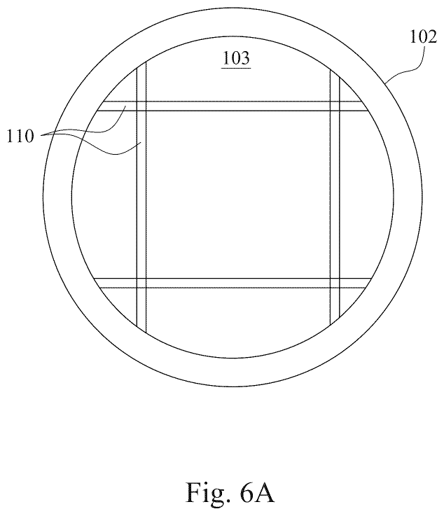

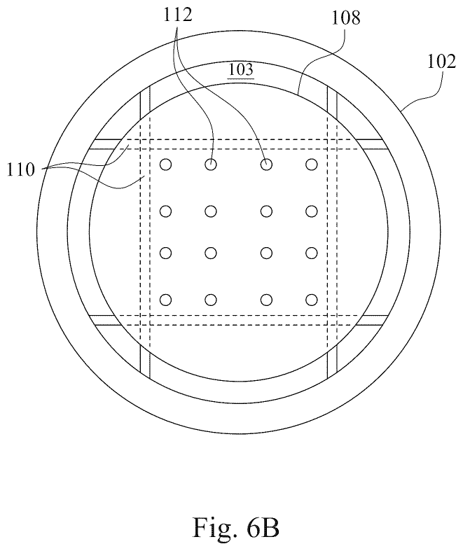

FIG. 6A is a top view of an interior volume 103 of a process chamber 102, in accordance with some embodiments. The process chamber 102 is one example of a process chamber that can be utilized in the systems of FIGS. 1-4. The top view of FIG. 6A illustrates a grid support 110 positioned within the interior volume 103 of the process chamber 102. The grid support 110 includes a frame made up of individual bars, rods, or other types of solid supports. The view of FIG. 6A does not illustrate the target support 104 and the target 106 that may be present within the interior volume 103 of the process chamber 102. A grid support 110 can have other shapes and configurations without departing from the scope of the present disclosure. The grid support 110 may include a conductive material, a dielectric material, a ceramic material, or other types of materials.

FIG. 6B illustrates the process chamber 102 of FIG. 6A with a circular grid 108 resting on the grid support 110. The portions of the grid support 110 below the grid 108 are illustrated in dashed lines. The grid 108 includes a plurality of apertures 112. A grid 108 having other shapes and configurations can be utilized on grid support 110 without departing from the scope of the present disclosure.

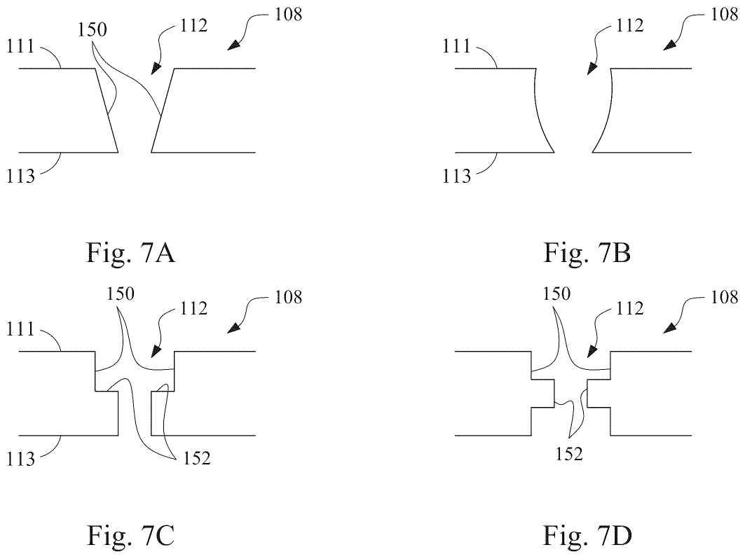

FIG. 7A is an enlarged cross-sectional view of a portion of a grid 108. The grid 108 of FIG. 7A is one example of a grid 108 that can be utilized in the systems of FIGS. 1-4. FIG. 7A illustrates that the aperture 112 of the grid 108 includes tapered sidewalls 150 such that the aperture 112 has a larger dimension, e.g., surface area, at a distal side 111 of the grid 108 than at the proximal side 113 of the grid 108. Alternatively, the aperture 112 can have a larger dimension, e.g., surface area, at the proximal side 113 than at the distal side 111. The sidewalls 150 are substantially straight and extend diagonally rather than straight vertically.

FIG. 7B is an enlarged cross-sectional view of a portion of a grid 108. The grid 108 of FIG. 7B is one example of a grid 108 that can be utilized in the systems of FIGS. 1-4. FIG. 7B illustrates that the aperture 112 of the grid 108 includes curved sidewalls 150 such that the aperture 112 has a larger dimension, e.g., surface area, at a distal side 111 of the grid 108 than at the proximal side 113 of the grid 108. Alternatively, the aperture 112 can have a larger dimension, e.g., surface area, at the proximal side 113 than at the distal side 111.

FIG. 7C is an enlarged cross-sectional view of a portion of a grid 108. The grid 108 of FIG. 7C is one example of a grid 108 that can be utilized in the systems of FIGS. 1-4. FIG. 7C illustrates that the aperture 112 of the grid 108 includes stepped sidewalls 150 such that the aperture 112 has a larger dimension, e.g., surface area, at a distal side 111 of the grid 108 than at the proximal side 113 of the grid 108. Alternatively, the aperture 112 can have a larger dimension, e.g., surface area, at the proximal side 113 than at the distal side 111. The sidewalls 150 include a step 152.

FIG. 7D is an enlarged cross-sectional view of a portion of a grid 108. The grid 108 of FIG. 7D is one example of a grid 108 that can be utilized in the systems of FIGS. 1-4. FIG. 7D illustrates that the aperture 112 of the grid 108 includes stepped sidewalls 150. The step 152 is positioned midway between the distal side 111 and the proximal side 113, such that the aperture 112 has a same dimension, e.g., surface area, at a distal side 111 of the grid 108 as at the proximal side 113 of the grid 108. Various other shapes can be utilized for the apertures 112 without departing from the scope of the present disclosure.

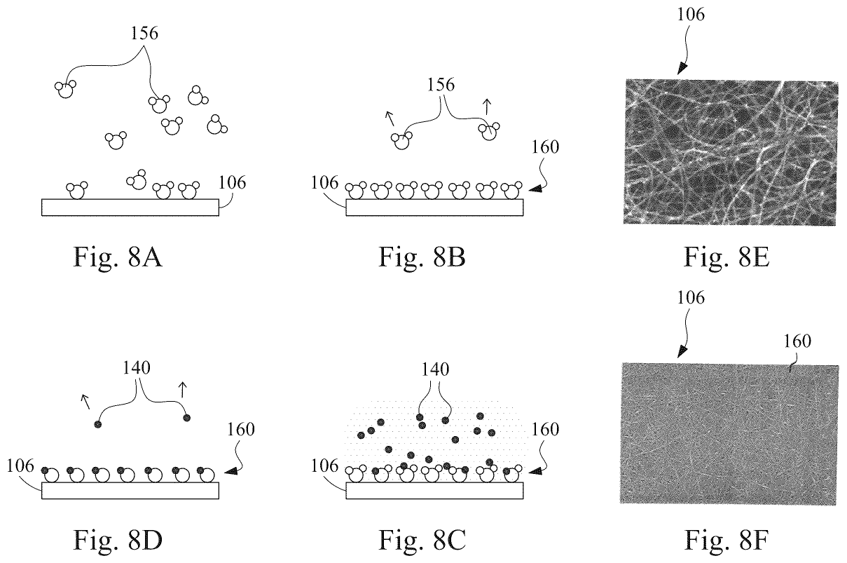

FIGS. 8A-8D are simplified cross-sectional views of a target 106 during a PEALD process for depositing a thin-film on the target 106, in accordance with some embodiments. The process shown in FIGS. 8A-8D deposits a single atomic or molecular layer of a thin-film on the target 106. In one embodiment, the target 106 is a porous substrate of carbon nanotubes. FIG. 8E is an enlarged top view of a portion of the target 106 including a plurality of intertwined carbon nanotubes. The process of FIGS. 8A-8D deposits a single molecular layer of silicon nitride on the carbon nanotubes target 106. Other targets and materials can be utilized without departing from the scope of the present disclosure.

With reference to FIGS. 2 and 8A, in FIG. 8A, a first process fluid is flowed from the first fluid source 118a through the non-operating plasma generation chamber 130, into the interior volume 103 of the process chamber 102. The fluid includes a plurality of precursor molecules 156. In one example, the precursor molecules 156 include SAM24 (C8H22N2Si). A carrier gas of molecular nitrogen (N2) may also be utilized to help flow the precursor molecules 156 onto the target 106. The precursor molecules 156 are adsorbed onto the exposed surface of the carbon nanotube target 106. The precursor molecules 156 form a single molecular layer 160 of a thin-film on the target 106, as shown in FIG. 8B.

In FIG. 8B, either or both of the purge sources 122a and 122b flow a purge gas into the interior volume 103 of the process chamber 102. The purge gas carries the remaining precursor molecules 156 and other byproducts out of the process chamber 102 via the exhaust outlets 132. In one example, the purge gas includes molecular nitrogen (N2), though other purge gases can be utilized without departing from the scope of the present disclosure.

In FIG. 8C, a second process fluid is flowed from the second fluid source 118b into the plasma generation chamber 130. The power supply 116 provides a voltage to the conductive coils 124 and a plasma is generated from the second process fluid within the plasma generation chamber 130. In one example, the second process fluid includes H2 or N2. The second process gas may be flowed with a flow rate at a temperature and pressure similar to the temperature and pressure utilized when flowing the first process gas. A plasma is generated such that hydrogen and nitrogen molecules are ionized. The result is that the plasma includes hydrogen and nitrogen ions and free electrons. A carrier gas may also be flowed into the process chamber 102 to carry the plasma particles 140 through one or more grids 108 onto the target 106. The carrier gas may include argon or other types of carrier gases and may have a flow rate of 80 sccm. The plasma particles may break a chemical bond in the layer 160 of the thin-film such that the composition of the thin-film is changed so that another round of the precursors can be deposited and broken apart to form a second layer of the thin-film. In one example, the thin-film is silicon nitride, though other thin-films can be utilized. Because the one or more grids 108 are utilized within the process chamber 102, the energy of the plasma particles 140 is reduced to a level that will not damage or break apart the carbon nanotubes of the target 106.

In FIG. 8D, either or both of the purge sources 122a and 122b flow a purge gas into the interior volume 103 of the process chamber 102. The purge gas carries in the remaining plasma particles 140 and carries the other byproducts out of the process chamber 102 via the exhaust outlets 132. In one example, the purge gas includes molecular nitrogen (N2), though other purge gases can be utilized without departing from the scope of the present disclosure.

FIG. 8F is a top view of the carbon nanotube target 106 after multiple molecular layers of silicon nitride have been formed on the carbon nanotubes. In one example, 20 cycles of the process shown in FIGS. 8A-8D are performed to form the conformal silicon nitride film on the carbon nanotubes shown in FIG. 8F. Other numbers of cycles can be utilized without departing from the scope of the present disclosure.

While FIGS. 8A-8F describe the process for depositing a thin-film of silicon nitride on a carbon nanotube target, in accordance with embodiments of the present disclosure, other types of thin-films can be deposited on the carbon nanotube target 106 or on a different type of target 106.

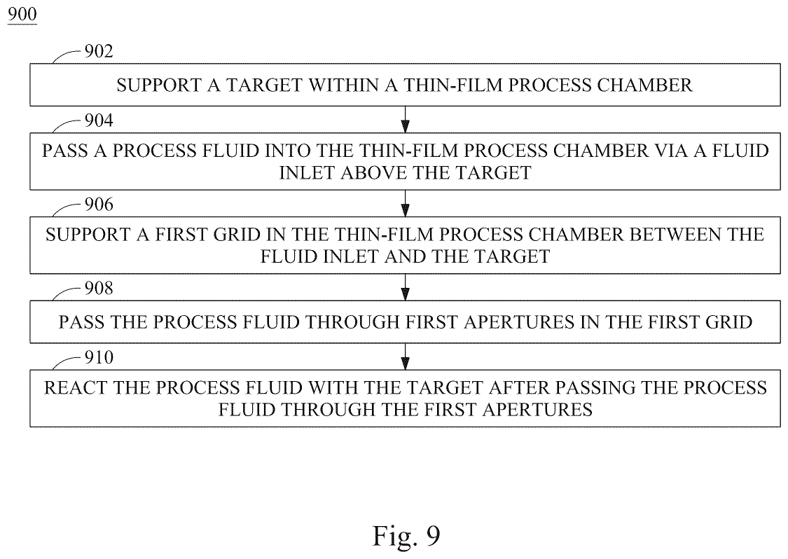

FIG. 9 is a flow diagram of a method 900 for performing a thin-film process on a target, according to some embodiments. The method 900 can utilize systems, components, and processes described in relation to FIGS. 1-8F. At 902, the method 900 includes supporting a target within a thin-film process chamber. One example of a target is the target 106 of FIG. 1. One example of process chamber is the process chamber 102 of FIG. 1. At 904, the method 900 includes passing a process fluid into the thin-film process chamber via a fluid inlet above the target. One example of process fluid is the plasma particles 140 of FIG. 2B. One example of a fluid inlet is the showerhead structure 126 of FIG. 2A. At 906, the method 900 includes supporting a first grid in the thin-film process chamber between the fluid inlet and the target. One example of a first grid is the grid 108 of FIG. 1. At 908, the method 900 includes passing the process fluid through first apertures in the first grid 108. One example of first apertures are the apertures 112 of FIG. 2A. At 910, the method 900 includes reacting the process fluid with the target after passing the process fluid through the first apertures.

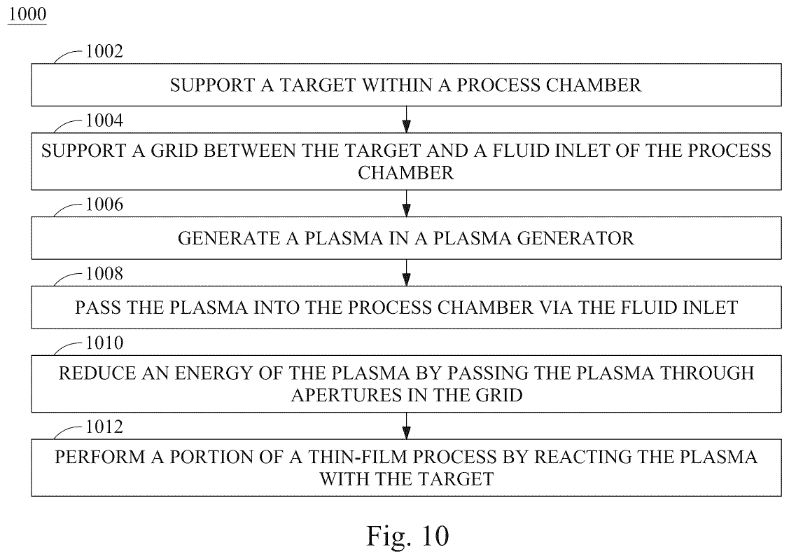

FIG. 10 is a flow diagram of a method 1000 for performing a thin-film process on a target, according to some embodiments. The method 1000 can utilize systems, components, and processes described in relation to FIGS. 1-9. At 1002, the method 1000 includes supporting a target within a process chamber. One example of a target is the target 106 of FIG. 1. One example of a process chamber is the process chamber 102 of FIG. 1. At 1004, the method 1000 includes supporting a grid between the target and a fluid inlet of the process chamber. One example of a grid is the grid 108 of FIG. 1. One example of a fluid inlet is the showerhead structure 126 of FIG. 2A. At 1006, the method 1000 includes generating a plasma in a plasma generator. One example of a plasma generator is the plasma generator 114 of FIG. 1. At 1008, the method 1000 includes passing the plasma into the process chamber via the fluid inlet. At 1010, the method 1000 includes reducing an energy of the plasma by passing the plasma through apertures in the grid. One example of apertures are the apertures 112 of FIG. 2A. At 1012, the method 1000 includes performing a portion of a thin-film process by reacting the plasma with the target.

In some embodiments, a system includes a process chamber including a fluid inlet configured to flow a process fluid into the process chamber, a target support within the process chamber below the fluid inlet and configured to support a target within the process chamber, and a first grid within the process chamber between the fluid inlet and the target support. The grid includes a first side distal to the target support, a second side proximal to the target support, and a plurality of first apertures extending between the first side and the second side above the target support.

In some embodiments, a method includes supporting a target within a thin-film process chamber, passing a process fluid into the thin-film process chamber via a fluid inlet above the target, and supporting a first grid in the thin-film process chamber between the fluid inlet and the target. The method includes passing the process fluid through first apertures in the first grid and reacting the process fluid with the target after passing the process fluid through the first apertures.

In some embodiments, a method includes supporting a target within a process chamber, supporting a grid between the target and a fluid inlet of the process chamber, and generating a plasma in a plasma generator. The method includes passing the plasma into the process chamber via the fluid inlet, reducing an energy of the plasma by passing the plasma through apertures in the grid, and performing a portion of a thin-film process by reacting the plasma with the target.

Embodiments of the present disclosure provide a plasma enhanced atomic layer deposition (PEALD) process system that can safely perform PEALD processes on sensitive target substrates without damaging the target substrates. A target is supported in a process chamber. A grid is positioned above the target in the process chamber. The grid has a first side distal to the target, a second side proximal to the target, and a plurality of apertures extending between the first side and the second side. During a PEALD process, a plasma is reacted with the target. However, before the plasma is reacted with the target, the energy of the plasma is reduced by passing the plasma through the apertures of the grid.

Embodiments of the present disclosure provide several benefits. The reduction in plasma energy by the grid prevents the plasma from damaging the target substrate. As a result, fewer substrates or circuits need to be scrapped. Furthermore, circuits and devices have better performance and thin films have higher quality.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

The various embodiments described above can be combined to provide further embodiments. Aspects of the embodiments can be modified, if necessary, to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A system, comprising:
a plasma assisted thin film deposition chamber including a fluid inlet configured to flow a process fluid into the plasma assisted thin film deposition chamber;
a target support within the plasma assisted thin film deposition chamber below the fluid inlet and configured to support a target within the plasma assisted thin film deposition chamber; and
a first grid within the plasma assisted thin film deposition chamber between the fluid inlet and the target support and including:
a first side distal to the target support;
a second side proximal to the target support; and
a plurality of first apertures extending between the first side and the second side above the target support.

2. The system of claim 1, further comprising a plasma generator configured to generate, from the process fluid, a plasma including plasma particles, wherein the first grid is configured to reduce an energy of the plasma particles before the plasma particles interact with a target supported by the target support.

3. The system of claim 2, further comprising a second grid within the plasma assisted thin film deposition chamber between the first grid and the target support and including:
a third side distal to the target support;
a fourth side proximal to the target support; and
a plurality of second apertures extending between the third side and the fourth side above the target support.

4. The system of claim 3, wherein the second apertures are laterally offset relative to the first apertures.

5. The system of claim 4, wherein the second apertures are laterally offset from the first apertures such that a vertical line passing through any of the first apertures does not pass through any of the second apertures.

6. The system of claim 3, wherein the first grid is vertically separated from the second grid by a distance between 1 mm and 10 mm.

7. The system of claim 1, wherein the fluid inlet is a showerhead structure, wherein the first grid is separated from the showerhead structure by a distance greater than 1 mm.

8. The system of claim 1, wherein the first apertures are wider at the first side than at the second side.

9. A system, comprising:
a thin-film process chamber;
a target support within the thin-film process chamber and configured to support a target;
one or more fluid inlets configured to flow plasma particles into the thin-film process chamber;
a grid support; and
a supported by the grid support and positioned between the one or more fluid inlets and the target support and including a plurality of first apertures configured to decrease an energy of the plasma particles before contacting the target.

10. The system of claim 9, comprising a showerhead structure including the one or more fluid inlets.

11. The system of claim 10, comprising a plasma generation chamber above the showerhead structure.

12. The system of claim 11, comprising one or more conductive coils above the showerhead structure and configured to generate plasma particles from a process fluid in the plasma generation chamber.

13. The system of claim 12, comprising one or more fluid sources configured to flow the process fluid into the plasma generation chamber.

14. The system of claim 12, wherein the one or more coils generate the plasma particles as part of an atomic layer deposition process configured to deposit a thin-film on the target.

15. The system of claim 14, wherein the target includes carbon nanotubes.

16. The system of claim 10, comprising a second grid between the target support and the first grid.

17. The system of claim 9, wherein the first apertures have a width between 1 mm and 30 mm.

18. A system, comprising:
a process chamber;
a target support within the process chamber and configured to support a target;
a first grid positioned above the target support and including first apertures;
a second grid positioned above the first grid and including second apertures;
a fluid inlet above the second grid.

19. The system of claim 18, wherein the first apertures have tapered sidewalls.

20. The system of claim 18, wherein the first grid and the second grid include a rare earth material.
